(19) United States
(12) Patent Application Publication
(10) Pub. No.: US 2010/0226508 A1
(43) Pub. Date: Sep. 9, 2010

(54) DEVICE AND METHOD FOR ADAPTING AN AUDIO SIGNAL TO A TRANSDUCER UNIT

(75) Inventors: Ronaldus Maria Aarts, Eindhoven (NL); Joris Adelbert Maria Nieuwendijk, Eindhoven (NL); Okke Ouweltjes, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., Eindhoven (NL)

(21) Appl. No.: 12/161,811

(22) PCT Filed: Jan. 23, 2007
(86) PCT No.: PCT/IB07/50224

§ 371 Date: Jul. 23, 2008

(30) Foreign Application Priority Data
Jan. 27, 2006 (EP) 06100928.8

(51) Int. Cl. H03G 5/00

(52) U.S. Cl. 381/99

(57) ABSTRACT

A device (30) for adapting an audio input signal (V1n) to a transducer unit (20) comprises: mapping means (10) for mapping input signal components from a first audio frequency range onto a second audio frequency range so as to produce a mapped audio signal (VM), wherein the second audio frequency range is narrower than the first audio frequency range, and wherein the transducer unit (20) has a maximum efficiency at the second audio frequency range, filter means (31) for filtering the input signal (V1n) so as to produce a filtered input signal (V1n′) having a third audio frequency range, and combination means (32) for combining the mapped audio signal (VM) and the filtered input signal (V1n′) so as to produce a transducer signal (VT). The first audio frequency range is preferably contained in the second audio frequency range, while the third audio frequency range may be adjacent the first audio frequency range. The second audio frequency range preferably extends within 5% of the Helmholtz frequency of the transducer unit (20).

The present invention relates to audio reproduction. More in particular, the present invention relates to a device and method for adapting an audio signal to a transducer unit.

It is well known that audio transducers, such as loudspeakers, have a limited frequency range in which they can faithfully render sound at a certain minimum sound level. High fidelity audio systems typically have relatively small transducers (tweeters) for reproducing the high frequency range, and relatively large transducers (woofers) for reproducing the low frequency range. As a result, the transducers units (that is, enclosures in which transducers are accommodated) required to reproduce the lowest audible frequencies (approximately 20-100 Hz) at a suitable sound level take up a substantial amount of space. Consumers, however, often prefer compact audio sets which necessarily have small transducer units.

It has been suggested to solve this problem by using psycho-acoustic phenomena such as “virtual pitch”. By creating harmonics of low-frequency signal components it is possible to suggest the presence of such signal components without actually reproducing these components. However, this solution is no substitute for actually producing low-frequency (“bass”) signal components.

International Patent Application WO 2005/027568 (Philips) discloses a device for concentrating a selected audio frequency range in a narrower audio frequency range. This is achieved by detecting first signal components in a first audio frequency range, generating second signal components in a second audio frequency range, and controlling the amplitude of the second signal components in response to the amplitude of the first signal components. As a result, dedicated transducers may be used which are particularly efficient in the narrower second frequency range. The original frequency range may contain the lower frequency signal components (bass components) of the audio signal.

Although this known device is very effective, it essentially produces sound of a narrow frequency band only. As a result, the sound produced by this known device is sometimes found to be too tonal.

It is an object of the present invention to overcome these and other problems of the Prior Art and to provide a device and method for adapting an audio signal to a transducer which allows an efficient sound reproduction in a wider frequency range. Accordingly, the present invention provides a device for adapting an audio input signal to a transducer unit, the device comprising:
mapping means for mapping input signal components from a first audio frequency range onto a second audio frequency range so as to produce a mapped audio signal, wherein the second audio frequency range is narrower than the first audio frequency range, and wherein the transducer unit has a maximum efficiency at the second audio frequency range,
filter means for filtering the input signal so as to produce a filtered input signal having a third audio frequency range, and
combination means for combining the mapped audio signal and the filtered input signal so as to produce a transducer signal.
   By providing mapping means for mapping input signal components from a first audio frequency range onto a second, narrower audio frequency range, the audio signal can be concentrated in the relatively narrow frequency range where the transducer unit is most efficient. By additionally providing filter means for selecting a third audio frequency range and then combining this third audio frequency range and the mapped second audio frequency range, an output signal having a wider frequency range is obtained while still preserving the advantages of frequency mapping.

It is noted that the filter means may be constituted by an all-pass filter if the third audio frequency range corresponds with the frequency range of the input audio signal. Alternatively, the filter means may be omitted.

It is preferred that the second audio frequency range is contained in the first frequency audio range. In this way, the first audio frequency range is effectively concentrated in the frequencies where the transducer unit is most efficient or most sensitive. However, it is also possible for the second audio frequency range to lie outside the first audio frequency range.

It is further preferred that the third audio range is adjacent the first audio range. In this way, the first and third audio frequency ranges together form a continuous frequency range. It is also possible for the first and third audio frequency ranges to overlap (when considered at a certain amplitude level, for example the well-known −3 dB level), in which case it may further be preferred that the second and third audio frequency ranges are non-overlapping, thus covering distinct frequencies.

It is preferred that the third audio frequency range is located between the first and the second sound pressure level (SPL) peak of the transducer unit, that is, between the frequencies at which the first and second SPL peak occur. In this way, it is assured that the third audio frequency range, which is fed to the transducer unit via the filter means, contains no resonance frequencies. Excessive sound levels at these resonance frequencies are thus avoided.

In an advantageous embodiment, the first audio frequency range has an upper boundary not exceeding 150 Hz, preferably not exceeding 120 Hz, more preferably approximately 100 Hz. The second audio frequency range may advantageously span less than 50 Hz, preferably less than 10 Hz, more preferably less than 5 Hz, and is preferably centered around approximately 55 Hz, although it may also be centered around, for example, approximately 50 or 60 Hz. The third audio frequency range may have a lower boundary of approximately 100 Hz and an upper boundary of approximately 150 to 200 Hz, depending on the transducer properties and the particular application.

The device may further comprise a notch filter unit and/or a gain control unit arranged in series with the filter unit. The notch filter unit preferably has a stop-band which includes a higher resonance frequency of the transducer unit.

The second audio frequency range may comprise a resonance frequency of the transducer unit. This resonance frequency preferably is the main resonance frequency, that is, the resonance frequency resulting in the highest SPL (Sound Pressure Level). Alternatively, when there are multiple resonance frequencies resulting in similar SPLs, the lowest of these frequencies may be used.

At this resonance frequency, the transducer unit has a high sensitivity and a very high transducer efficiency may be obtained, in particular when the transducer has a high force factor (B1). In another advantageous embodiments, the second audio frequency range contains the Helmholtz frequency of the transducer unit. In such embodiments, a relatively high force factor (B1) of the transducer is also preferred.

By operating the transducer unit at its Helmholtz frequency, the transducer displacement (the cone displacement in the case of a loudspeaker) is minimal while the sound level is high. It is noted that the Helmholtz frequency referred to here is the “anti-resonance” frequency of the transducer unit (that is, the transducer including the enclosure in which it is accommodated). The dimensions and features of the enclosure, together with the transducer characteristics, determine the Helmholtz frequency.

The transducer unit may advantageously be accommodated in an enclosure comprising an open-ended tube, in particular when the second audio frequency range contains the Helmholtz frequency of the transducer unit. In this way, a compact yet efficient transducer unit is obtained. The tube is not necessarily straight but may be curved or folded to provide a compact and/or attractive design. The tube may, for example, have a labyrinth structure.

It is noted that mapping an audio signal onto the Helmholtz frequency of a transducer is described in more detail in European Patent Application 05108634.6 (File Reference PH 000806 EP1) and the patents and patent applications derived therefrom, the entire contents of which are herewith incorporated in this document.

The mapping means serve to map the first audio frequency range onto the second audio frequency range, thus effecting a frequency conversion. In a preferred embodiment, the mapping means comprise:
a detection unit for detecting first signal components in a first audio frequency range,
a generator unit for generating second signal components in a second audio frequency range, and
an amplitude control unit for controlling the amplitude of the second signal components in response to the amplitude of the first signal components.
   The detection unit may comprise an envelope detector known per se, or any other suitable detector. The generator unit may comprise a Voltage Controlled Oscillator (VCO) known per se, while the amplitude control unit may comprise a multiplication circuit known per se. The mapping means may additionally comprise a filter unit, preferably a band-pass filter unit, for selecting an audio frequency range to be mapped. The selected audio frequency range corresponds with the first audio frequency range mentioned above.

The present invention also provides an audio system, comprising a device as defined above. The audio system may further comprise an amplifier, one or more additional transducers, and/or a sound source such as a CD player, a DVD player, a radio tuner, an MP3 player, an internet terminal, and/or a computer. The audio system may be used in (flat) television devices, in car sound systems, and in other applications.

The present invention further provides a method of adapting an audio input signal to a transducer unit, the method comprising the steps of:
mapping input signal components from a first audio range onto a second audio range so as to produce a mapped audio signal, wherein the second audio frequency range is narrower than the first audio frequency range, and wherein the transducer unit has a maximum efficiency at the second audio frequency range,
filtering the input signal so as to produce a filtered input signal having a third audio range, and
combining the mapped audio signal and the filtered input signal so as to produce a transducer signal.
   The filtering step may involve a band-pass filter or an all-pass filter. Alternatively, the filtering step may be omitted.

It is preferred that the second audio range is contained in the first audio range, and/or that the third audio range is adjacent the first audio range. Further embodiments of the method according to the present invention will become apparent from the description below.

The present invention additionally provides a computer program product for carrying out the method as defined above. A computer program product may comprise a set of computer executable instructions stored on a data carrier, such as a CD or a DVD. The set of computer executable instructions, which allow a programmable computer to carry out the method as defined above, may also be available for downloading from a remote server, for example via the Internet.

The present invention will further be explained below with reference to exemplary embodiments illustrated in the accompanying drawings, in which:

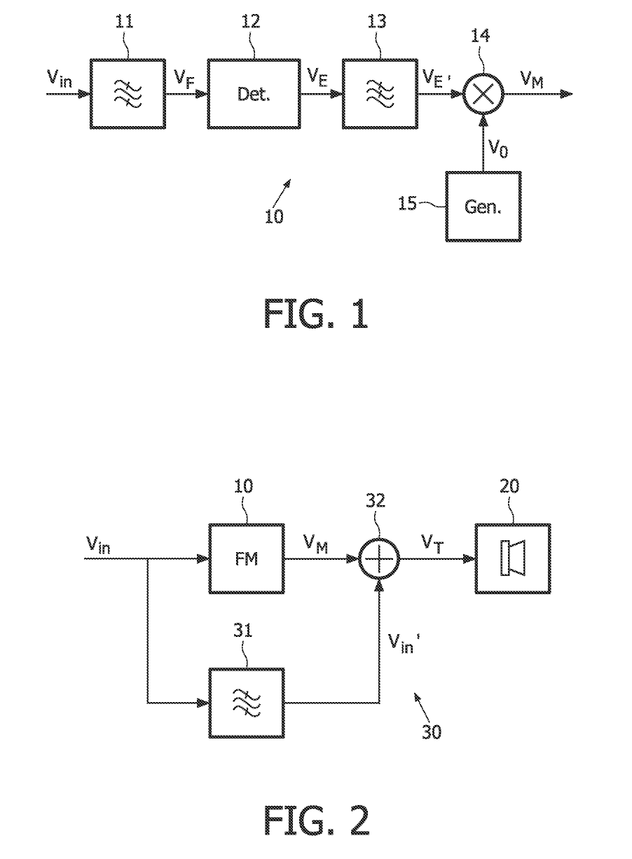

FIG. 1 schematically shows a frequency mapping device as may be used in the present invention.

FIG. 2 schematically shows a first embodiment of a frequency adaptation device according to the present invention.

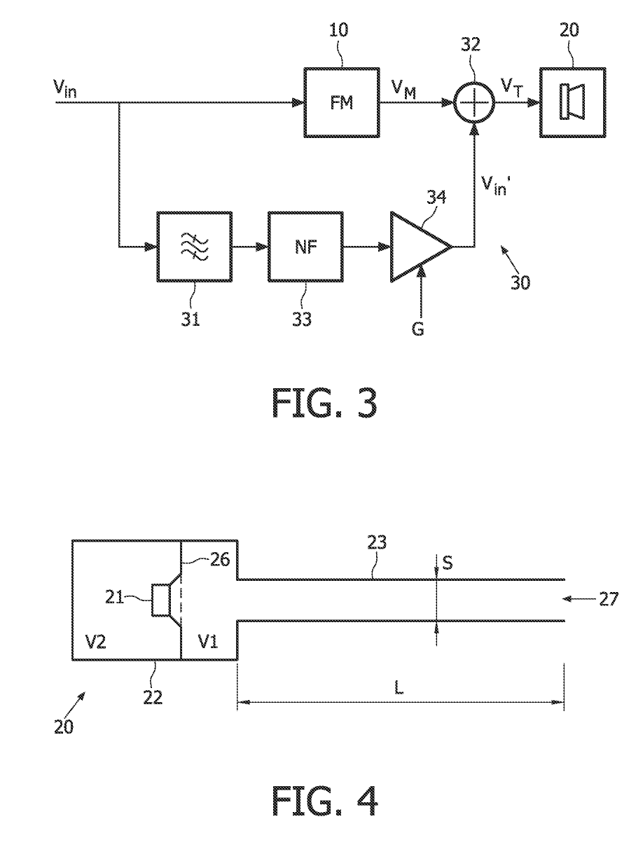

FIG. 3 schematically shows a second embodiment of a frequency adaptation device according to the present invention.

FIG. 4 schematically shows a transducer unit as may be used in the present invention.

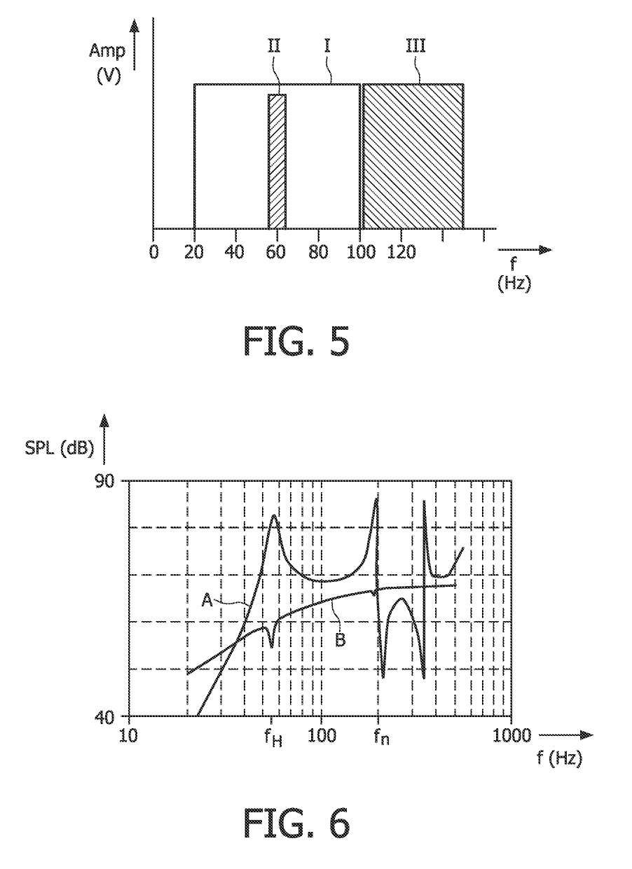

FIG. 5 schematically shows audio frequency ranges in accordance with the present invention.

FIG. 6 schematically shows transducer unit characteristics as are utilized in the present invention.

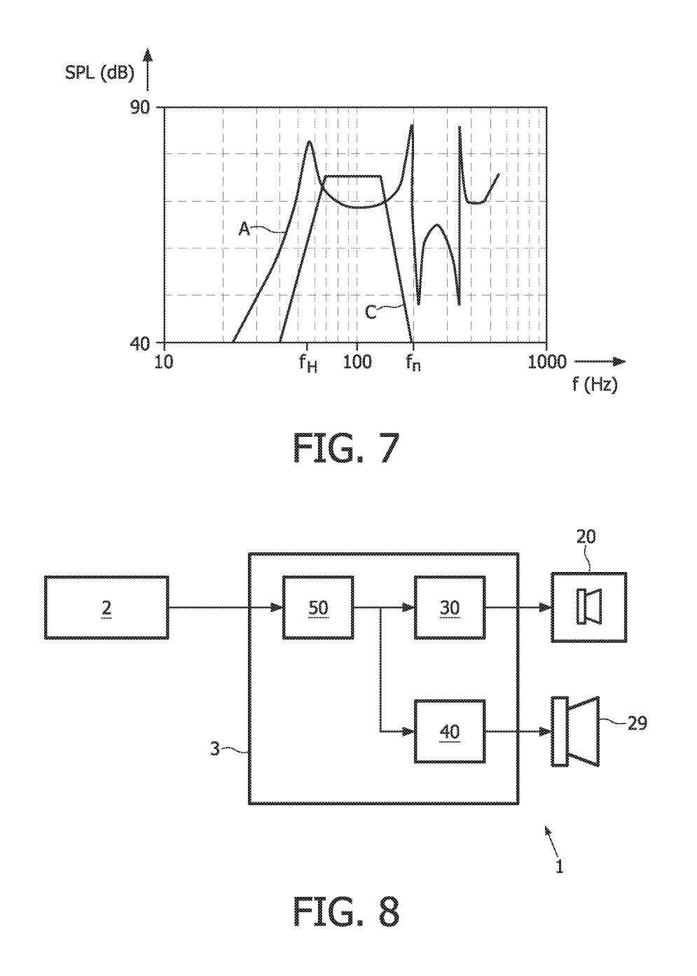

FIG. 7 schematically shows transducer and filter characteristics as are utilized in the present invention.

FIG. 8 schematically shows an audio system according to the present invention.

The audio frequency mapping device 10 shown merely by way of non-limiting example in FIG. 1 comprises a band-pass filter 11, a detector 12, an (optional) low-pass filter 13, a multiplier 14 and a generator 15. The filter 11 has a pass-band which corresponds to a first audio frequency range I (as will later be explained in more detail with reference to FIG. 5), thus eliminating all frequencies outside the first range. The detector 12 detects the signal V_{F} received from the filter 11. The detector 12 preferably is a peak detector known per se, but may also be an envelope detector known per se. In a very economical embodiment, the detector may be constituted by a diode.

The signal V_{E} produced by the detector 12 represents the amplitude of the combined signals present within the first range I (see FIG. 5). Multiplier 14 multiplies this signal V_{E}, or its filtered version V_{E}′ if the optional filter 13 is present, by a signal V₀ having a frequency f_{w}. This signal V₀ may be generated by a suitable generator 15. The output signal V_{M} of the multiplier 14 has an average frequency approximately equal to f_{w} while its amplitude is dependant on the signals contained in the first audio frequency range I. By varying the generator frequency f_{w}, the average frequency and therefore the location of the second audio frequency range II can be varied. The audio frequency mapping device 10 is described in more detail in International Patent Application WO 2005/027568 referred to above, the entire contents of which are herewith incorporated in this document.

The output signal V_{M} may be fed to a transducer, such as a loudspeaker. In some embodiments, the loudspeaker may be designed to operate at a frequency at which it has a high efficiency, for example at a resonance frequency. However, the signal V_{M} has a very narrow bandwidth at the generator frequency f_{w}. The resulting sound is therefore essentially limited to this narrow bandwidth and will therefore appear “tonal”. In order to solve this problem, the present invention feeds at least part of the original audio signal to the same transducer or transducer unit, as is illustrated in FIGS. 2 and 3.

The merely exemplary audio signal adaptation device 30 of the present invention which is schematically illustrated in FIG. 2 comprises an audio frequency mapping device 10, a filter unit 31 and a combination unit 32, and is coupled to a transducer unit 20 which includes a transducer. The audio frequency mapping device 10 preferably corresponds with the device 10 of FIG. 1, although this is not essential and other mapping devices capable of mapping a first audio frequency range onto a second, narrower audio frequency range may be used.

The audio signal adaptation device 30, and hence the audio frequency mapping device 10, receives an audio input signal Vᵢₙ which may have a typical audio frequency range, that is from approximately 20 Hz to approximately 15 kHz or higher. In some applications, the audio input signal Vᵢₙ may be filtered prior to being fed to the audio signal adaptation device 30 and may therefore have a more limited bandwidth. In some applications, the audio input signal Vᵢₙ may be limited to bass frequencies, ranging from approximately 20 Hz to 200 Hz.

The audio frequency mapping (FM) device 10 outputs a signal V_{M} to the combination unit 32. In parallel with the mapping device 10, a filter unit 31 is arranged, which is also coupled to the combination unit 32. The filter unit 31 receives the input audio signal Vᵢₙ and filters this signal so as to select a frequency range (the third frequency range III in FIG. 5). Typically, therefore, the filter unit 31 will comprise a band-pass filter having a pass band ranging from, for example, 100 to 150 Hz. The filtered audio input signal Vᵢₙ′ is fed to the combination unit 32, where it is combined with the signal V_{M} to produce the transducer signal V_{T}. The combination unit 32 may be constituted by an addition unit known per se. The transducer signal V_{T} is fed to the transducer unit 20.

It can be seen that the transducer 21 receives the combination of the relatively narrow-band mapped audio signal V_{M} and the filtered input signal Vᵢₙ′. The device 10 may, for example, map the (first) frequency range 20-100 Hz onto an extremely narrow (second) range centered at 55 Hz, while the filter unit 31 has a pass-band having a (third) range from 100 to 150 Hz. In this example, the input signal frequencies from 20 Hz to 150 Hz are effectively reproduced by the device 30. In some embodiments, the filter unit 31 may be constituted by an all-pass filter, although a band-pass filter is preferred.

An alternative embodiment of the audio signal adaptation device 30 of the present invention is schematically illustrated in FIG. 3. The embodiment of FIG. 3 additionally comprises a notch filter (NF) unit 33 and a gain adjustment unit 34, both of which are arranged in series with the filter unit 31. In the embodiment shown, both are arranged between the filter unit 31 and the combination unit 32, but this is not essential.

The notch filter unit 33 serves to remove the frequencies corresponding with any further resonance frequencies of the transducer or transducer unit, as will later be explained in more detail with reference to FIG. 7. The gain adjustment unit 34 is preferably constituted by a controlled amplifier having an adjustable gain G and serves to control the amplitude of the signal Vᵢₙ′ relative to the signal V_{M} so as to provide a well-balanced transducer signal V_{T}. It will be understood that the gain adjustment unit 34 may also be arranged before the notch filter 33, or between the audio frequency mapping unit 10 and the combination unit 32. In the embodiment of FIG. 3, the transducer signal V_{T} is fed to a transducer unit 20, which is preferably arranged to operate at its resonance frequency and/or its Helmholtz frequency.

The transducer unit 20 shown merely by way of non-limiting example in FIG. 4 comprises an enclosure 22 in which a transducer 21, such as a loudspeaker, is mounted. In the embodiment of FIG. 4, the enclosure 22 comprises two chambers which define a first volume V1 and a second volume V2 respectively, as well as a tube 23. The volumes V1 and V2 are divided by a partition 26 which supports the transducer 21. The first volume V1 is in open communication with the tube 23, while the second volume V2 is closed. In the embodiment shown the tube 23, which forms an integral part of the enclosure 22, does not project into any chamber, while the transducer faces the tube 23. It will be understood that other arrangements are possible, for example an arrangement in which the transducer 21 faces away from the tube 23.

The tube 23, which has an open end 27, has a length L and an internal cross-sectional surface area S which contribute to determining the Helmholtz frequency of the transducer unit 20. The surface area S defines the effective radiating surface of the transducer unit 20. The tube 23 shown in FIG. 4 is straight but in alternative embodiments the tube may be folded, curved and/or have a labyrinth type structure, thus providing a compact design. It is noted that the embodiments shown are not necessarily rendered to scale.

In an alternative embodiment (not shown), the enclosure 22 has only a single chamber defining a single volume V1. In addition, the front of the transducer (typically, the cone of the loudspeaker) 21 faces outwards, away from the tube 23. However, the transducer may also face towards the tube 23, as shown in FIG. 4.

In either embodiment, it is preferred that no damping material is present in the enclosure, and the tube 23 is relatively long while the (first) volume V1 is relatively small. In some further embodiments, however, small amounts of damping material may be present, and the relative dimensions of the tube 23 and the volume V1 may differ from those shown.

As explained above with reference to FIGS. 2 & 3, the frequency mapping device 10 produces a signal V_{M} having a center frequency f_{w}. In the present invention, the dimensions of the enclosure 22 are chosen such that the Helmholtz frequency f_{H} of the transducer unit 20 is approximately equal to the frequency f_{w} of the signal V_{M}. Expressed mathematically:

f_{w}≈f_{H} (1)

It is preferred that the deviation from equality is less than 10%, preferably less than 5%, still more preferably less than 1%.

The Helmholtz frequency can be defined by the electrical impedance of the transducer, when mounted in an enclosure, as illustrated in FIG. 4. The (absolute value of the) electrical impedance reaches a maximum at a first resonance frequency and a second resonance frequency. Between these resonance frequencies, the electrical impedance reaches a minimum at a frequency f_{H}. This frequency f_{H} is the Helmholtz frequency of the transducer unit: the frequency at which the so-called anti-resonance occurs in the transducer unit (20 in FIG. 4), resulting in a (local) minimum displacement of the transducer 21. The electrical impedance may reach further maxima at further resonance frequencies, but these are not relevant to the present invention.

A preferred distribution of audio frequency ranges is schematically illustrated in FIG. 5. A first frequency range I is shown, in this non-limiting example, to extend from 20 Hz to 100 Hz. This first frequency range I of the audio input signal (Vᵢₙ in FIGS. 2 & 3) is mapped onto a second frequency range II, which is the present example extends approximately from 50 to 60 Hz. It can be seen that the second frequency range II (signal V_{M} in FIGS. 2 and 3) is narrower than and included in the first frequency range I.

In accordance with the present invention, the transducer unit (20 in FIGS. 2 & 4) receives not only the second frequency range II but also the third frequency range III. It can be seen that in the present example, the third frequency range III extends from 100 Hz to 150 Hz, thus adding valuable bass frequencies.

In the example of FIG. 5 there is no overlap between the first frequency range I and the third frequency range III. This is, however, not essential and some overlap of these ranges may be desirable. However, any overlap between the second frequency range II and the third frequency range III is preferably avoided, at least at a certain amplitude level, such as the −3 dB level.

The frequency characteristics of a transducer unit (20 in FIG. 4) are illustrated in FIGS. 6 & 7. In FIG. 6, the sound pressure level (SPL) produced by a transducer unit is shown as a function of the (logarithmic) frequency. The sound pressure level (SPL) of a transducer unit, that is a transducer mounted in an enclosure such as the enclosure 22 in FIG. 4, may be represented by graph A. Graph B represents the SPL of the transducer without an enclosure, but mounted in an infinite baffle and driven such that the cone displacement is the same as for the system corresponding with graph A.

As can be seen, graph A exhibits a (first) peak at the frequency f_{H}≈55 Hz. For this reason, the second frequency range II of FIG. 5 is centered around 55 Hz. It can thus be seen that the frequencies of the first frequency range I in FIG. 5 (20 to 100 Hz) are mapped upon the frequency range (50 to 60 Hz) where the transducer has the highest SPL (for a given input power). It can further be seen that graph B has a dip at about 55 Hz. This is the Helmholtz frequency of the transducer unit, at which a resonance in the volume V1 (FIG. 4) and the tube 23 (also FIG. 4) of the transducer enclosure cause a high SPL at a very low cone displacement. The significant difference in SPL between the peak of graph A and the trough in graph B, both at f_{H}, is a clear advantage of the transducer unit of the present invention.

It can also be seen from FIG. 6 that further resonances occur at approximately 200 Hz. To suppress any such resonances, the embodiment of FIG. 3 contains a notch filter 33 having a center frequency (notch frequency fₙ) equal to approximately 200 Hz.

Graph C of FIG. 7 illustrates the band-pass of the filter unit 31. In the example shown, the pass-band extends approximately from 70 to 150 Hz, substantially between the first SPL peak (at f_{H}) and the second SPL peak (at fₙ) in graph A. Accordingly, this frequency range is additionally fed to the transducer, thus broadening the reproduced frequency range. As the transducer is not as effective in this frequency range as around the frequency f_{H}, the amplitude of the corresponding signal (Vᵢₙ′ in FIG. 3) may be relatively increased (gain adjustment unit 34 in FIG. 3) because the required cone excursion is at these higher frequencies less that at f_{H}.

An audio system according to the present invention is schematically illustrated in FIG. 8. An audio processing device 3 is shown to comprise an amplification unit 50, a frequency adaptation device 30 and a processing unit 40. The frequency adaptation device 30 and a processing unit 40 are arranged in parallel.

An input signal Vᵢₙ produced by a sound source 2 is fed to the amplification unit 50 where it is amplified and then fed to both the device 30 and the processing unit 40. The frequency adaptation device 30 selects a frequency range, for example the bass frequency range, and maps this frequency range onto the Helmholtz frequency of the (schematically represented) first transducer unit 20, while also feeding another selected frequency range to the same transducer unit 20. The processing unit 40 may comprise a further amplifier to amplify all frequencies and feed the resulting signal to the (schematically represented) second transducer unit 29. Additionally, or alternatively, the processing unit 40 may comprise filters for filtering certain frequencies, and/or a (power) amplifier arranged between the frequency adaptation device 30 and the transducer unit 20.

In the case of a multiple channel audio system, such as a stereo system or a 5.1 system, multiple frequency adaptation devices 30 may be provided. Alternatively, a single frequency adaptation device 30 may be shared by two or more channels, the (bass) signals being added to produce a shared signal which is to be adapted by the frequency adaptation device 30.

In a preferred embodiment, the processing unit 40 comprises delay elements for delaying the signal fed to the second transducer unit 29 in such a way that the sound pressure of the first transducer unit 20 is approximately equal to the sound pressure of the second transducer unit 29, in particular at a certain time instant. In this embodiment, the processing unit 40 introduces delays to equal any delays introduced by the device 10.

The first transducer unit 20 is preferably a transducer unit according to the present invention which is designed to operate at its Helmholtz frequency, while the second transducer unit 29 may be a conventional transducer unit having one or more transducers.

The sound source 2 may be constituted by any suitable sound source, such as a radio tuner, a CD or DVD player, an MP3 or AAC player, an Internet terminal, and/or a computer having suitable audio storage means.

Applications of the present invention include, but are not limited to, (flat) television apparatus, television receiver devices, set-top box devices, satellite receiver devices, home sound systems, professional sound systems, and car sound systems.

The present invention is based upon the insight that the quality of the sound reproduced by a transducer unit operating at a narrow, mapped frequency range can be significantly improved by adding part of the original audio signal to the frequency mapped audio signal.

It is noted that any terms used in this document should not be construed so as to limit the scope of the present invention. In particular, the words “comprise(s)” and “comprising” are not meant to exclude any elements not specifically stated. Single (circuit) elements may be substituted with multiple (circuit) elements or with their equivalents.

It will be understood by those skilled in the art that the present invention is not limited to the embodiments illustrated above and that many modifications and additions may be made without departing from the scope of the invention as defined in the appending claims.

1. A device (30) for adapting an audio input signal (Vᵢₙ) to a transducer unit (20), the device comprising:
mapping means (10) for mapping input signal components from a first audio frequency range (I) onto a second audio frequency range (II) so as to produce a mapped audio signal (V_{M}), wherein the second audio frequency range (II) is narrower than the first audio frequency range (I), and wherein the transducer unit (20) has a maximum efficiency at the second audio frequency range (II),
filter means (31) for filtering the input signal (Vᵢₙ) so as to produce a filtered input signal (Vᵢₙ′) having a third audio frequency range (III), and
combination means (32) for combining the mapped audio signal (V_{M}) and the filtered input signal (Vᵢₙ′) so as to produce a transducer signal (V_{T}).

2. The device according to claim 1, wherein the second audio frequency range (II) is contained in the first audio frequency range (I).

3. The device according to claim 1, wherein the third audio frequency range (III) is adjacent the first audio frequency range (I).

4. The device according to claim 1, wherein the third audio frequency range (III) is located between the first and the second sound pressure level peak of the transducer unit (20).

5. The device according to claim 1, wherein the first audio frequency range (I) has an upper boundary not exceeding 150 Hz, preferably not exceeding 120 Hz, more preferably approximately 100 Hz,

6. The device according to claim 1, wherein the second audio frequency range (II) spans less than 50 Hz, preferably less than 10 Hz, more preferably less than 5 Hz, and/or wherein the second audio frequency range (II) is centered around approximately 55 Hz.

7. The device according to claim 1, wherein the second audio frequency range (II) contains the main resonance frequency of the transducer unit (20).

8. The device according to claim 1, wherein the second audio frequency range (II) contains the Helmholtz frequency of the transducer unit (20).

9. The device according to claim 1, wherein the transducer unit (20) comprises a transducer (21) mounted in an enclosure (22) having an open-ended tube (23).

10. The device according to claim 9, wherein the open-ended tube (23) is curved and/or folded.

11. The device according to claim 1, wherein the mapping means (10) comprise:
a detection unit (12) for detecting first signal components in a first audio frequency range (I),
a generator unit (15) for generating second signal components in a second audio frequency range (II), and
an amplitude control unit (14) for controlling the amplitude of the second signal components in response to the amplitude of the first signal components.

12. The device according to claim 1, further comprising a notch filter unit (33) and/or a gain control unit (34) arranged in series with the filter unit (31).

13. An audio system (1), comprising a device (30) according to claim 1.

14. A method of adapting an audio input signal (Vᵢₙ) to a transducer unit (20), the method comprising the steps of:
mapping input signal components from a first audio frequency range (I) onto a second audio frequency range (II) so as to produce a mapped audio signal (V_{M}), wherein the second audio frequency range (II) is narrower than the first audio frequency range (I), and wherein the transducer unit (20) has a maximum efficiency at the second audio frequency range (II),
filtering the input signal (Vᵢₙ) so as to produce a filtered input signal (Vᵢₙ′) having a third audio frequency range (III), and
combining the mapped audio signal (V_{M}) and the filtered input signal (Vᵢₙ′) so as to produce a transducer signal (V_{T}).

15. The method according to claim 14, wherein the second audio frequency range (II) is contained in the first audio frequency range (I).

16. The method according to claim 14, wherein the third audio frequency range (III) is adjacent the first audio frequency range (I).

17. The method according to claim 14, wherein the third audio frequency range (III) is located between the first and the second sound pressure level peak of the transducer unit (20).

18. The method according to claim 14, wherein the first audio frequency range (I) has an upper boundary not exceeding 150 Hz, preferably not exceeding 120 Hz, more preferably approximately 100 Hz.

19. The method according to claim 14, wherein the second audio frequency range (II) spans less than 50 Hz, preferably less than 10 Hz, more preferably less than 5 Hz, and/or wherein the second audio frequency range (II) is centered around approximately 55 Hz.

20. The method according to claim 14, wherein the second audio frequency range (II) contains the main resonance frequency of the transducer unit (20).

21. The method according to claim 14, wherein the second audio frequency range (II) contains the Helmholtz frequency of the transducer unit (20).

22. The method according to claim 14, wherein the transducer unit (20) comprises a transducer (21) mounted in an enclosure (22) having an open-ended tube (23).

23. The method according to claim 14, wherein the mapping step comprises the sub-steps of:
detecting first signal components in a first audio frequency range (I),
generating second signal components in a second audio frequency range (II), and
controlling the amplitude of the second signal components in response to the amplitude of the first signal components.

24. A computer program product for carrying out the method according to claim 14.
